(19) United States
(12) Patent Application Publication
(10) Pub. No.: US 2005/0145872 A1
(43) Pub. Date: Jul. 7, 2005

(54) High performance nitride-based light-emitting diodes

(76) Inventors: Chao-Yi Fang, Taoyuan City (TW); Kuang-Neng Yang, Hsinchu Hsien (TW); Fen-Ren Chien, Yung-Ho City (TW); Lung-Chien Chen, Hsin-Chuang City (TW)

Correspondence Address: SUPREME PATENT SERVICES, POST OFFICE BOX 2339, SARATOGA, CA, 95070, US

(21) Appl. No.: 10/747,934

(22) Filed: Dec. 29, 2003

(51) Int. Cl. H01L 33/00

(52) U.S. Cl. 257/103; 257/98

(57) ABSTRACT

A nitride-based light-emitting diode is provided, including a substrate having a light extraction layer grown on the substrate, and a nitride semiconductor epitaxy layer grown on the light extraction layer. The external quantum efficiency is improved by changing the traveling path of the emitted light and by matching the refraction index between the light extraction layer and the substrate. Also, a high power nitride-based light-emitting diode having a sacrificial layer is disclosed. A sacrificial layer is used for growing a light-emitting structure, and a binding layer made of two or more metals or alloys is used to bind the grown light-emitting structure and a substrate with high thermoconductivity. The sacrificial layer is later entirely etched away with a chemical solution used in a chemical etching process, and the nitrogen epitaxy structure is placed on the substrate with high thermoconductivity so that the diode can operate at high electrical current to improve external quantum efficiency.

### FIELD OF THE INVENTION

The present invention relates to a nitride-based light-emitting diode and, more particularly, to a nitride-based light-emitting diode grown on a substrate with a light extraction layer.

The present invention also relates to a high power nitride-based light-emitting diode and, more particularly, to a high power nitride-based light-emitting diode grown on a substrate with a sacrificial layer.

### BACKGROUND OF THE INVENTION

The external quantum efficiency of conventional light-emitting diodes suffers from the failure of emitted light penetration, resulted from the refraction index difference between the semiconductor material and the external material. Take nitride-based light-emitting diode as example. The refraction index of the nitride semiconductor grown on the substrate is about 2.0-2.5, the refraction index of the Al₂O₃ substrate is 1.77, while the refraction index of epoxy resin used in conventional packaging methods is 1.5. Therefore, most of the emitted light runs and is absorbed inside the diode, and this results in reducing the external quantum efficiency to less than 20%.

U.S. Pat. No. 2002/0,125,485, by Steigerwald et al., disclosed a method for improving light output by roughening the back and the sides of the substrate. However, the proposed method is difficult to materialize and has a poor yield rate.

U.S. Pat. No. 6,515,306, by Kuo et al., disclosed a method to replace the conventional translucent ohmic contact metal layer with a transparent conductive electrode for reducing the light absorption and improving the external quantum efficiency. However, in realistic application, the life span of this type of diodes is still unsatisfactorily short.

Besides, the conventional nitride-based light-emitting diodes use an epitaxy based on Al₂O₃ as the substrate, which is an insulator, so that the P-type and N-type electrodes are placed on the same side. This also reduces the effective light-emitting area on the die. Furthermore, because the substrate is made of material with low thermoconductivity, the diodes are not suitable for operating at high electrical current.

U.S. Pat. No. 6,420,242, by Cheung, et al., disclosed a method of using excimer laser to separate the Al₂O₃ substrate and the nitride semiconductor epitaxy layer. However, this method is difficult to materialize and also has a poor yield rate. All the aforementioned methods suffer the drawbacks and limitations of the conventional nitride-based light-emitting diodes.

The present inventor, based on years of experience and research, provides the present invention to solve the aforementioned obstacles.

### SUMMARY OF THE INVENTION

To solve the first part of the problems described in the aforementioned methods, it is necessary to reduce the light absorption in the epitaxy layer. Therefore, the present invention grows a light extraction layer on the Al₂O₃ substrate in a pattern, and then grows a nitride semiconductor epitaxy layer on the light extraction layer. When the electrical current flows through the diode, the light changes its direction because of the light extraction layer when traveling from light-emitting layer to the substrate. The light previously absorbed by the epitaxy layer can now penetrate the diode and emit.

In addition, by matching the refraction index of the light extraction layer and the refraction index of the substrate, the present invention greatly improves the external quantum efficiency of the diode.

Furthermore, the present invention uses the light extraction layer to greatly reduce the defects of the nitride semiconductor epitaxy layer, and improves the internal quantum efficiency of the diode.

The present invention provides a simple structure for pre-epitaxy manufacturing process in order to improve the external quantum efficiency of the diode.

To solve the second part of the problems described in the aforementioned methods, the present invention uses the following method: first, growing a sacrificial layer in a pattern on the Al₂O₃ substrate, and then growing a nitride semiconductor epitaxy layer on top of the sacrificial layer. When the light-emitting structure of the nitride semiconductor and the substrate with high thermoconductivity are bound together by the binding layer, the sacrificial layer can be entirely etched away by a chemical solution used in a chemical etching process. Finally, the light-emitting structure of the nitride semiconductor is placed on the substrate with the high thermoconductivity. Because the substrate has high thermoconductivity, the diode can operate at high electrical current in order to improve the external quantum efficiency of the diode.

In addition, the use of a sacrificial layer in the present invention can reduce the defects of the nitride semiconductor epitaxy layer, and improves the internal quantum efficiency of the diode.

The present invention provides a simple structure for pre-epitaxy manufacturing process in order to manufacture a high power nitride-based light-emitting diode.

These and other objects, features and advantages of the invention will be apparent to those skilled in the art, from a reading of the following brief description of the drawings, the detailed description of the preferred embodiments, and the appended claims.

### BRIEF DESCRIPTION OF THE DRAWINGS

FIG. 1 shows a cross-sectional view of the structure of a conventional nitride-based light-emitting diode.

FIG. 2 shows a top view of a conventional nitride-based light-emitting diode.

FIG. 3 shows a top view of the light extraction layer on the substrate-in the first embodiment of the present invention.

FIG. 4 shows a top view of the light extraction layer on the substrate in the second embodiment of the present invention.

FIG. 5 shows a top view of the light extraction layer on the substrate in the third embodiment of the present invention.

FIG. 6 shows a top view of the light extraction layer on the substrate in the fourth embodiment of the present invention.

FIG. 7 shows a top view of the light extraction layer on the substrate in the fifth embodiment of the present invention.

FIG. 8 shows a top view of the light extraction layer on the substrate in the sixth embodiment of the present invention.

FIG. 9 shows a top view of the light extraction layer on the substrate in the seventh embodiment of the present invention.

FIG. 10 shows a top view of the light extraction layer on the substrate in the eighth embodiment of the present invention.

FIG. 11 shows a top view of the light extraction layer on the substrate in the ninth embodiment of the present invention.

FIG. 12 shows a top view of the light extraction layer on the substrate in the tenth embodiment of the present invention.

FIG. 13 shows a side view of the structure of a nitride-based light-emitting diode of present invention, indicating the size of the light extraction layer.

FIG. 14 shows a cross-sectional view of a first preferred structure of a nitride-based light-emitting diode of present invention.

FIG. 15 shows a cross-sectional view of a second preferred structure of a nitride-based light-emitting diode of present invention.

FIG. 16 shows a cross-sectional view of a conventional nitride-based light-emitting diode.

FIG. 17 shows a cross-sectional view of another conventional nitride-based light-emitting diode.

FIG. 18 shows a top view of the sacrificial layer on the substrate in the eleventh embodiment of the present invention.

FIG. 19 shows a top view of the sacrificial layer on the substrate in the twelfth embodiment of the present invention.

FIG. 20 shows a top view of the sacrificial layer on the substrate in the thirteenth embodiment of the present invention.

FIG. 21 shows a top view of the sacrificial layer on the substrate in the fourteenth embodiment of the present invention.

FIG. 22 shows a top view of the sacrificial layer on the substrate in the fifteenth embodiment of the present invention.

FIG. 23 shows a top view of the sacrificial layer on the substrate in the sixteenth embodiment of the present invention.

FIG. 24 shows a top view of the sacrificial layer on the substrate in the seventeenth embodiment of the present invention.

FIG. 25 shows a top view of the sacrificial layer on the substrate in the eighteenth embodiment of the present invention.

FIG. 26 shows a top view of the sacrificial layer on the substrate in the nineteenth embodiment of the present invention.

FIG. 27 shows a top view of the sacrificial layer on the substrate in the twentieth embodiment of the present invention.

FIG. 28 shows a flowchart of the manufacturing process of a high power nitride-based light-emitting diode of present invention.

FIG. 29 shows a cross-sectional view of a first preferred structure of a high power nitride-based light-emitting diode of present invention.

FIG. 30 shows a cross-sectional view of a second preferred structure of a high power nitride-based light-emitting diode of present invention.

### DETAILED DESCRIPTION OF THE PREFERRED EMBODIMENTS

To achieve the objects described in the first part of the summary, the present invention grows a light extraction layer on the substrate before the epitaxy growth process. Then, a nitride semiconductor epitaxy layer is grown on the light extraction layer. After the micro-lithography, evaporation, etching, pressing, and dicing steps to fabricate the light-emitting diode. When the electrical current flows through the diode, the light reaches the light extraction layer and changes its traveling path before the light emitted from active layer reaching the substrate. Therefore, the light that would be absorbed previously by the epitaxy layer in the conventional techniques is able to penetrate the epitaxy layer and emits from the diode. Furthermore, by matching the refraction index of the light extraction layer and the refraction index of the substrate, it is able to greatly improve the external quantum efficiency.

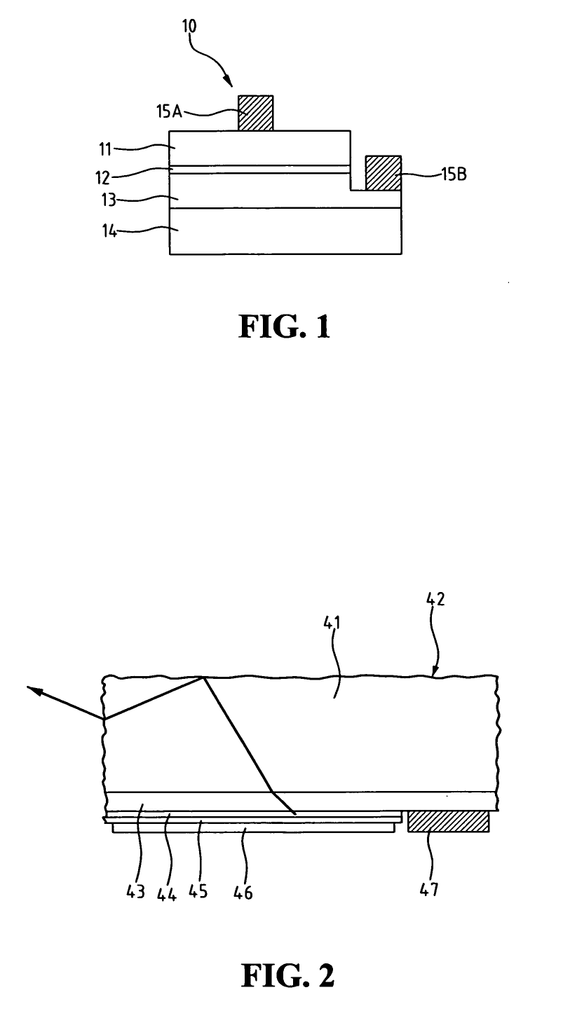

Referring to FIG. 1, a conventional nitride-based light-emitting diode structure 10 comprises an Al₂O₃ substrate 14, a P-type nitride semiconductor epitaxy layer 11, and an N-type nitride semiconductor epitaxy layer 13. Expitaxy layers 11, 13 are grown on the substrate 14 with a conventional epitaxy growing technique. The light emitted in the diode, due to the refraction index difference between the nitride semiconductor and the Al₂O₃ substrate, is unable to penetrate from inside, and is absorbed by the epitaxy layer. Therefore, the external quantum efficiency of the diode is usually far less than 20%.

FIG. 2 shows the method disclosed in U.S. Pat. No. 2002/0,125,485, by Steigerwald et al. The method, by roughening the back and the sides of the substrate to improve light emitting, is difficult to materialize and has a poor yield rate.

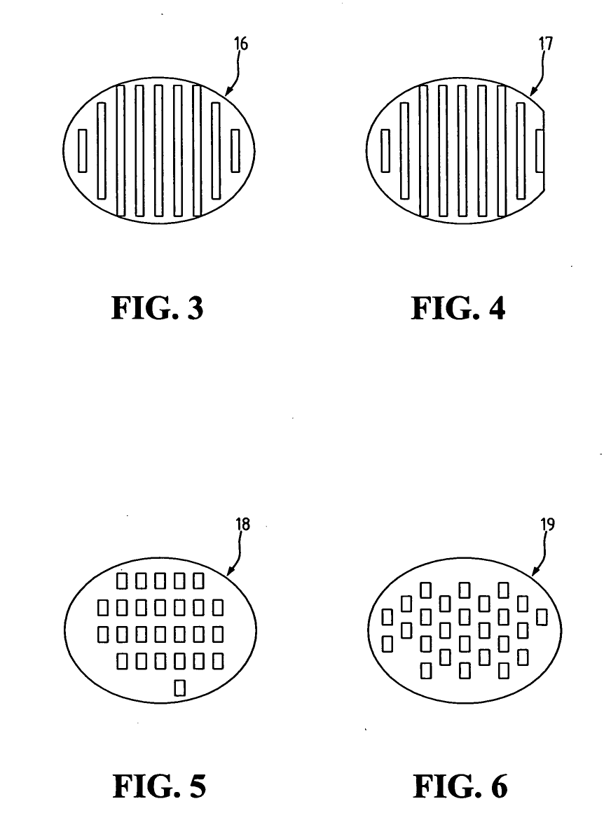

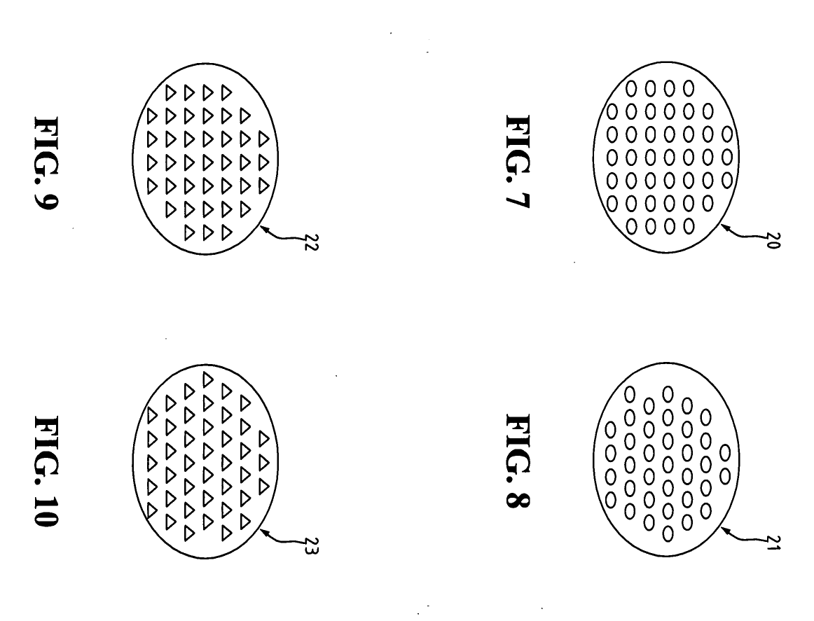

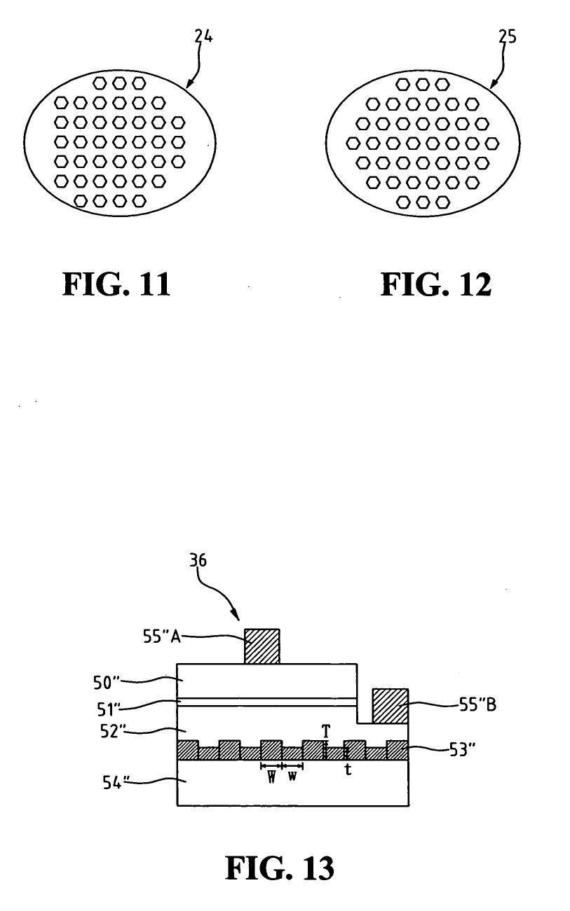

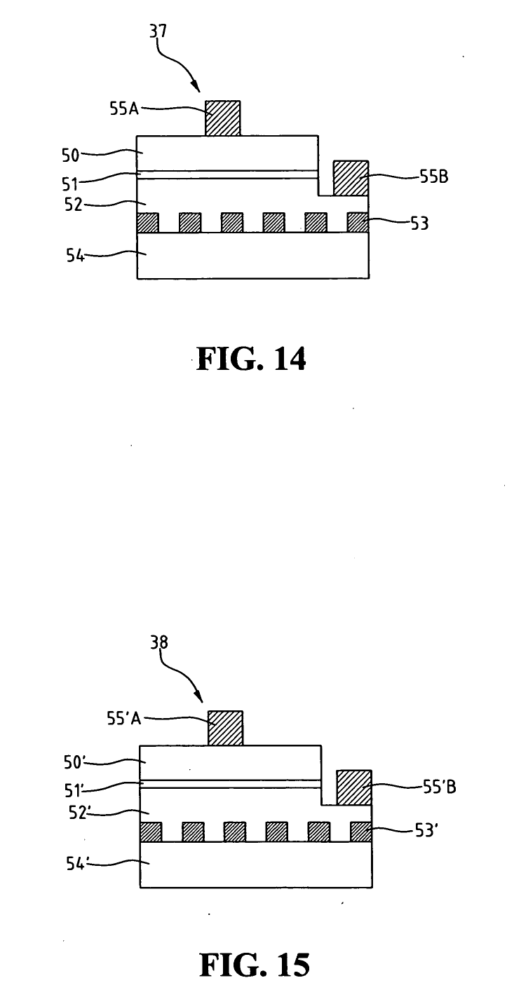

To improve the shortcoming in the conventional techniques, a light extraction layer 16-25 is fabricated on the Al₂O₃ substrate, in a pattern as shown in FIGS. 3-12. The light extraction layer can be fabricated with any of the following methods: epitaxy deposition, sputtering, plasma deposition, chemical vapor deposition (CVD), beam evaporation. The size of the light extraction layer is as shown in FIG. 13, where t=0-99% T, with T being 0.01-3 μm, and w=0-100% W, with w being 0.1-1000 μm. After the light extraction layer is fabricated, the Al₂O₃ substrate is placed in an epitaxy growing machine for fabricating nitride semiconductor epitaxy growth, followed by micro-lithography, evaporation, etching, pressing, and dicing steps to manufacture the light-emitting diode. By varying the size of the light extraction layer to match the epitaxy growth condition, the light-emitting diodes with the structures 37, 38 can be manufactured, as shown in FIGS. 14, 15.

The material for the light extraction layer can be ITO, In₂O₃, TiO₂, ZrO₂, ZnS, ZnO, ZnSe, or MgO.

The light-emitting diode manufactured with the techniques described above can reduce the amount of light that is absorbed by the epitaxy layer, and improves the external quantum efficiency to nearly 30%.

The present invention uses the light extraction layer to reduce the defects of the nitride semiconductor layer, and improves the internal quantum efficiency of the diode.

The present invention provides a simple structure, prior to the epitaxy growth process, to improve the external quantum efficiency of the light-emitting diode.

To achieve the objects described in the second part of the summary, the present invention grows a sacrificial layer on the substrate before the epitaxy growth process in order to manufacture a high power nitride-based light-emitting diode. Then, a nitride semiconductor epitaxy layer is grown on the sacrificial layer. After using a chip binding technique to bind the light-emitting structure of the nitride semiconductor and the substrate with high thermoconductivity together, the sacrificial layer can be entirely etched away by a chemical solution used in a chemical etching process. The nitride semiconductor epitaxy layer is placed on the substrate with high thermoconductivity. Then, the micro-lithography, evaporation, etching, pressing, and dicing steps are used to fabricate the light-emitting diode. Finally, the epitaxy layer is placed on the substrate with high thermoconductivity. This achieves a vertical structure that requires a single conductive wire. Furthermore, because the substrate has high thermoconductivity, the diode can operate at high electrical current to improve the light output power.

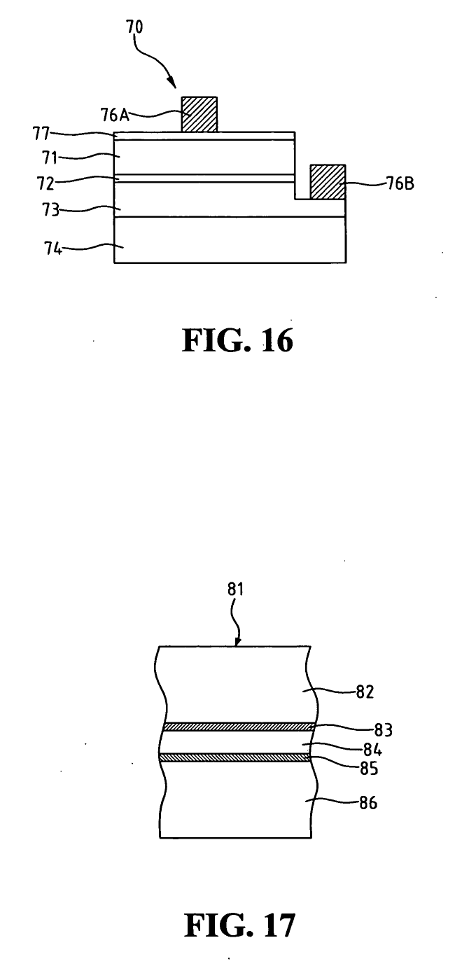

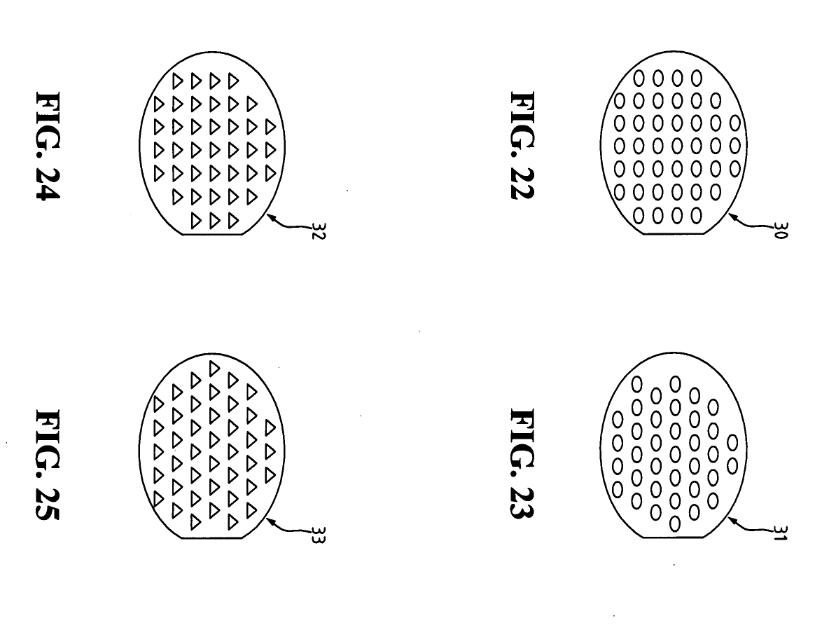

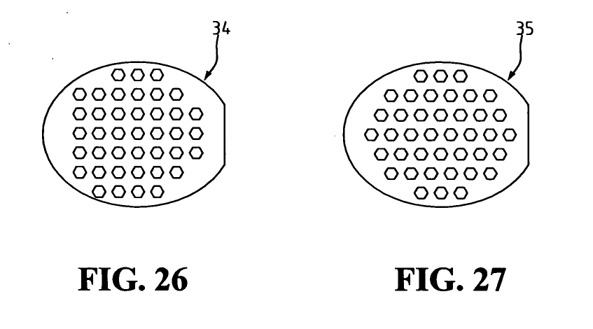

Referring to FIGS. 16-30 for the following description and first referring to FIG. 16, a conventional nitride-based light-emitting diode structure 70 comprises an Al₂O₃ substrate 74, a P-type nitride semiconductor epitaxy layer 71, and an N-type nitride semiconductor epitaxy layer 73. Expitaxy layers 71, 73 are grown on the substrate 74 with a conventional epitaxy growing technique. Because the substrate 74 is an insulator, both P-type and N-type electrodes are placed on the same side of the substrate 74. This reduces the effective area for light emitting on the diode. In addition, because Al₂O₃ has low thermoconductivity, the diode cannot operate at high electrical current.

FIG. 17 shows the method disclosed in U.S. Pat. No. 6,420,242, by Cheung et al. The method, by using an excimer laser to separate the Al₂O₃ substrate and the nitride semiconductor epitaxy layer, is difficult to materialize and has a poor yield rate.

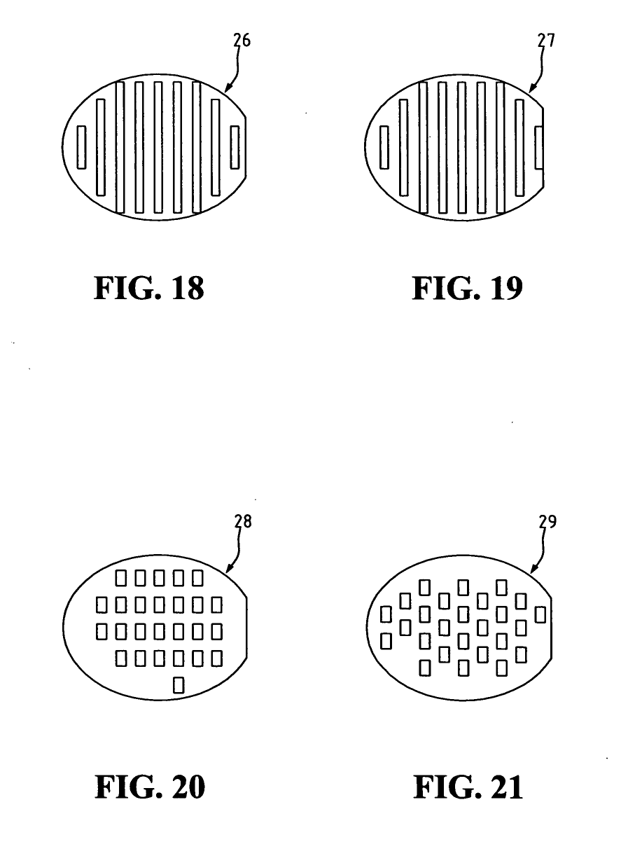

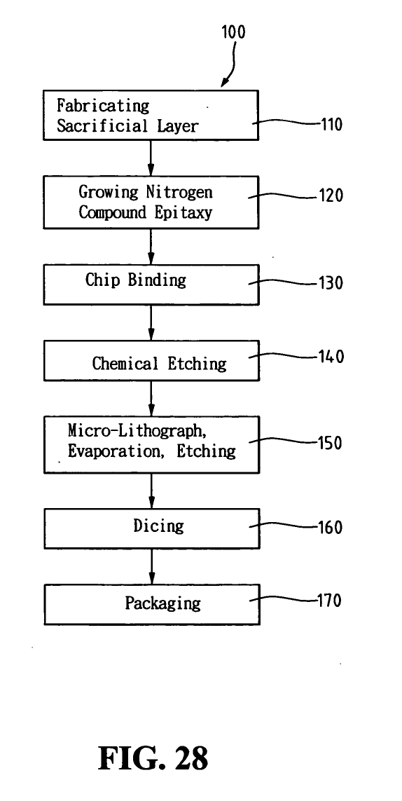

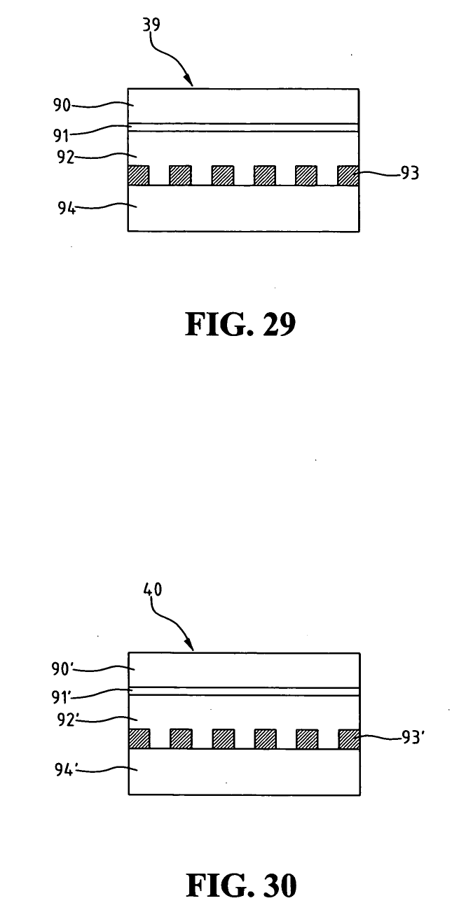

To improve the shortcoming in the conventional techniques, a sacrificial layer 26-35 is fabricated on the Al₂O₃ substrate, in a pattern as shown in FIGS. 18-27. Referring to FIG. 28 for the flowchart of method 100: fabricating a sacrificial layer using any of the following methods: epitaxy deposition, sputtering, plasma deposition, sol-gel, hot isostaic pressing, chemical vapor deposition (CVD), beam evaporation (step 110). The thickness of the sacrificial layer is 0.01-3 μm, and width 0.1-1000 μm. After the sacrificial layer is fabricated, the Al₂O₃ substrate is placed in an epitaxy growing machine for fabricating nitride semiconductor epitaxy growth using any of the following methods: MOCVD, induced electrode coupling plasma CVD, sputtering, HVPE, sol-gel (step 120). In step 130, a chip binding technique is used to bind the light-emitting structure of the nitride semiconductor and the substrate having high thermoconductivity with a binding layer, followed by etching away the entire sacrificial layer with a chemical solution used in a chemical etching process (step 140). The nitride epitaxy layer can then be replaced, in large area, on a substrate with high thermoconductivity. Finally, a light-emitting diode is manufactured with micro-lithography, evaporation, etching (step 150), pressing, dicing (step 160), and packaging (step 170) steps. By varying the size of the sacrificial layer to match the epitaxy growth condition, the light-emitting diodes with the structures 39, 40 can be manufactured, as shown in FIGS. 29, 30.

The material for the sacrificial layer can be ITO, In₂O₃, TiO₂, ZrO₂, ZnS, ZnO, ZnSe, or MgO.

The high power light-emitting diode manufactured with the techniques described above can operate at an electrical current five times higher than that of a conventional light-emitting diode.

The present invention uses the sacrificial layer to reduce the defects of the nitride semiconductor layer, and improves the internal quantum efficiency of the diode.

The present invention provides a simple structure, prior to the epitaxy growth process, to achieve a high power light-emitting diode.

While the invention has been described in connection with what is presently considered to the most practical and preferred embodiment, it is to be understood that the invention is not to be limited to the disclosed embodiments, but, on the contrary, it should be clear to those skilled in the art that the description of the embodiment is intended to cover various modifications and equivalent arrangement included within the spirit and scope of the appended claims.

1. A nitride-based light-emitting diode (LED), comprising:
a substrate,
a light extraction layer grown on the substrate, and
a nitride semiconductor epitaxy layer grown on the light extraction layer,
wherein the traveling path of the emitted light can be changed by the light extraction layer to avoid the absorption by the epitaxy layer and to emit from the diode to improve the external quantum efficiency, and the external quantum efficiency is improved by matching the refraction index between the light extraction layer and the substrate.

2. The LED as claimed in claim 1, wherein the substrate is made of Al₂O₃.

3. The LED as claimed in claim 1, wherein the substrate is made of SiC.

4. The LED as claimed in claim 1, wherein the light extraction layer is made of a material selected from a group consisting of ITO, In₂O₃, TiO₂, ZrO₂, ZnS, ZnO, ZnSe, and MgO.

5. The LED as claimed in claim 1, wherein the light extraction layer has the thickness T=0.01-3 μm.

6. The LED as claimed in claim 1, wherein the light extraction layer has the width W=0.1-10000 μm.

7. A high power nitride-based light-emitting diode (LED) having a sacrificial layer, comprising:
a substrate,
a sacrificial layer grown on the substrate,
a nitride semiconductor epitaxy layer grown on the sacrificial layer,
a substrate with high thermoconductivity, and
a binding layer, for binding the light-emitting structure of the nitride semiconductors and the substrate with high thermoconductivity,
wherein the sacrificial layer in the light-emitting structure is entirely etched away with a chemical solution used in a chemical etching process, and the resulted nitride epitaxy structure is placed on the substrate with high thermoconductivity so that the diode can operate at high electrical current to improve external quantum efficiency.

8. The LED as claimed in claim 7, wherein the substrate is made of Al₂O₃.

9. The LED as claimed in claim 7, wherein the light extraction layer is made of a material selected from a group consisting of ITO, In₂O₃, TiO₂, ZrO₂, ZnS, ZnO, ZnSe, and MgO.

10. The LED as claimed in claim 7, wherein the sacrificial layer has the thickness of 0.01-3 μm.

11. The LED as claimed in claim 7, wherein the sacrificial layer has the width 0.1-1000 μm.

12. The LED as claimed in claim 7, wherein the substrate with high thermoconductivity has thermoconductivity higher than 150 W/m-k.

13. The LED as claimed in claim 7, wherein the substrate with high thermoconductivity is made of one of the following materials: semiconductor, metal, or alloy.

14. The LED as claimed in claim 7, wherein the binding layer comprises at least one of the following materials: Al, Ag, Au, Ni, Cu, Pt, Ti, or Pd.

15. The LED as claimed in claim 7, wherein the binding layer is fabricated using sputtering, deposition, or electroplating.

16. The LED as claimed in claim 7, wherein the Al₂O₃ substrate is rid of by using a chemical etching process.
